(19) United States
(12) Patent Application Publication
(10) Pub. No.: US 2025/0188598 A1
(43) Pub. Date: Jun. 12, 2025

(54) STEP COVERAGE IMPROVER, METHOD OF FORMING THIN FILM USING STEP COVERAGE IMPROVER, SEMICONDUCTOR SUBSTRATE INCLUDING THIN FILM, AND SEMICONDUCTOR DEVICE INCLUDING SEMICONDUCTOR SUBSTRATE

(71) Applicant: SOULBRAIN CO., LTD., Gyeonggi-do (KR)

(72) Inventors: Seung Hyun LEE, Gyeonggi-do (KR); Jae Sun JUNG, Gyeonggi-do (KR); Chang Bong YEON, Gyeonggi-do (KR); Deok Hyun KIM, Gyeonggi-do (KR)

(21) Appl. No.: 18/847,195

(22) PCT Filed: Mar. 17, 2023
(86) PCT No.: PCT/KR2023/003581

§ 371 Date: Sep. 13, 2024

(30) Foreign Application Priority Data
Mar. 28, 2022 (KR) 10-2022-0037732
Oct. 25, 2022 (KR) 10-2022-0138088

(51) Int. Cl. C23C 16/02; H01L 21/02

(52) U.S. Cl. CPC C23C 16/0272; H01L 21/02205; H01L 21/0228

(57) ABSTRACT

The present invention relates to a step coverage improver, a method of forming a thin film using the step coverage improver, a semiconductor substrate including the thin film, and a semiconductor device including the semiconductor substrate. According to the present invention, by providing a compound with a predetermined structure as the step coverage improver, by forming a deposition layer with a uniform thickness as a shielded area on a substrate due to the difference in adsorption distribution of the compound, the deposition rate of the thin film may be reduced, and the thin film growth rate may be appropriately reduced. In addition, even when forming a thin film on a substrate with a complex structure, step coverage and the thickness uniformity of a thin film may be improved, and impurities may be greatly reduced.

### TECHNICAL FIELD

The present invention relates to a step coverage improver, a method of forming a thin film using the step coverage improver, a semiconductor substrate including the thin film, and a semiconductor device including the semiconductor substrate. More particularly, according to the present invention, by providing a compound with a predetermined structure, by forming a deposition layer with a uniform thickness as a shielded area on a substrate due to the difference in adsorption distribution of the compound, the deposition rate of the thin film may be reduced, and the thin film growth rate may be appropriately reduced. In addition, even when forming a thin film on a substrate with a complex structure, step coverage and the thickness uniformity of a thin film may be improved, and impurities may be greatly reduced.

### BACKGROUND ART

As the integration of memory and non-memory semiconductor devices increases, the microstructure of a substrate is becoming increasingly complex.

For example, the ratio of the width to depth of the microstructure (hereinafter referred to as the ‘aspect ratio’) is increasing to 20:1 or more, and even to 100:1 or more. As the aspect ratio increases, it becomes difficult to form a deposition layer with a uniform thickness along the plane of the complex microstructure.

Accordingly, step coverage, which defines the thickness ratio of deposition layers formed at the top and bottom in the depth direction of the microstructure, remains at the level of 90%. Accordingly, the expression of the electrical characteristics of a device becomes increasingly difficult. Since a step coverage of 100% means that deposition layers formed on the upper and lower parts of the microstructure have the same thickness, it is necessary to develop a technology that can achieve step coverage close to 100%.

That is, to provide excellent and uniform physical properties to a thin film deposited on a substrate, it is essential that the thin film has high step coverage. Accordingly, the atomic layer deposition (ALD) process, which uses surface reactions, is used rather than the chemical vapor deposition (CVD) process, which mainly uses gaseous reactions. However, there are still problems in implementing 100% step coverage.

When increasing deposition temperature to achieve 100% step coverage, it is difficult to achieve step coverage. First, in a deposition process using a precursor and a reactant, an increase in the deposition temperature leads to a steep increase in the thin film growth rate (GPC). In addition, even when the ALD process is performed at 300° C. to alleviate the increase in GPC due to the increase in deposition temperature, the deposition temperature increases during the process. Accordingly, the problem still remains.

In addition, high-temperature processes are required to realize metal oxide films with excellent film quality in semiconductor devices. A study has been reported in which the concentration of carbon and hydrogen remaining in a thin film was reduced by increasing the atomic layer deposition temperature to 400° C. (See the paper J. Vac. Sci. Technol. A, 35(2017) 01B130).

However, as the deposition temperature increases, it becomes difficult to ensure step coverage. First, in a deposition process using a precursor and a reactant, an increase in deposition temperature may lead to a sharp increase in thin film growth rate (GPC). In addition, even when a known shielding agent is applied to reduce the increase in GPC with increasing deposition temperature, it is confirmed that GPC increases by about 10% at 300° C. That is, when deposition is performed at temperatures above 360° C., it is difficult to expect the GPC reduction effect provided by the conventionally known shielding agent.

Therefore, there is a need to develop a thin film formation method that allows the formation of a thin film with a complex structure effectively even at high temperatures, reduces the residual amount of impurities, and improves step coverage and the thickness uniformity of a thin film and a semiconductor substrate including the thin film.

### DISCLOSURE

### Technical Problem

Therefore, the present invention has been made in view of the above problems, and it is one object of the present invention to provide a step coverage improver, a method of forming a thin film using the step coverage improver, and a semiconductor substrate including the thin film. According to the present invention, by forming a deposition layer with a uniform thickness on a substrate by the difference in adsorption distribution of a step coverage improver as a shielded area for thin films, the deposition rate of the thin film may be reduced, and the thin film growth rate may be appropriately reduced. In addition, even when forming a thin film on a substrate with a complex structure, step coverage and the thickness uniformity of a thin film may be greatly improved.

It is another object of the present invention to improve the density, electrical properties, and dielectric properties of a thin film by improving the crystallinity and oxidation fraction of the thin film.

The above and other objects can be accomplished by the present invention described below.

### Technical Solution

In accordance with one aspect of the present invention, provided is a step coverage improver including a compound represented by Chemical Formula 1 below.

### Chemical Formula 1

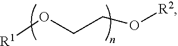

wherein R1 and R2 are independently H or an alkyl group having 1 to 5 carbon atoms, and n is an integer from 2 to 4.

The step coverage improver may include one or more selected from compounds represented by Chemical Formulas 1-1 to 1-6 below.

### [Chemical Formulas 1-1 to 1-6]

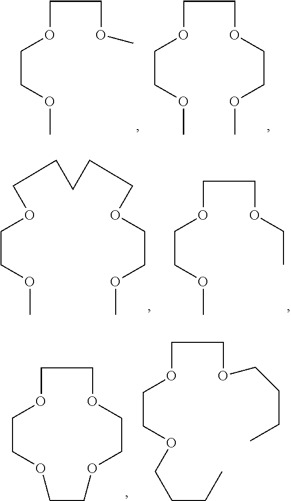

The step coverage improver may have a deposition rate reduction rate of 30% or more as calculated by Equation 1 below.

Deposition rate reduction rate=[{(DRᵢ)−(DR_{f})}/(DRᵢ)]×100 [Equation 1]

In Equation 1, deposition rate (DR, Å/cycle) is the speed at which a thin film is deposited. In the deposition of a thin film formed from a precursor and a reactant, DRᵢ (initial deposition rate) is the deposition rate of the thin film formed without adding a step coverage improver. DR_{f} (final deposition rate) is the deposition rate of the thin film formed by adding the step coverage improver during the above process. Here, the deposition rate (DR) is a value measured at room temperature and pressure using an ellipsometer for a thin film with a thickness of 3 to 30 nm, and is expressed in a unit of Å/cycle.

The step coverage improver may have a refractive index of 1.38 or more, 1.38 to 1.5, 1.38 to 1.45, or 1.39 to 1.44.

The step coverage improver may provide a shielded area for an oxide film, a nitride film, a metal film, or a selective thin film thereof.

The shielded area may be formed on the entire or part of a substrate on which the oxide film, the nitride film, the metal film, or the selective thin film thereof is formed.

Based on 100% of a total area of the substrate, a shielded area may occupy 10 to 95% of the entire substrate or a portion of the substrate, and an unshielded area may occupy the remainder.

When a total area of the substrate is 100%, a first shielded area may occupy 10 to 95% of a total area of the entire substrate or a portion of the substrate, a second shielded area may occupy 10 to 95% of the remaining area, and an unshielded area may occupy the remaining area.

The thin film may improve step coverage in a process of forming a laminated film of one or more selected from the group consisting of Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd.

The thin film may be used as a diffusion barrier film, an etching stop film, an electrode film, a dielectric film, a gate insulating film, a block oxide film, or a charge trap, and may improve step coverage during the formation process thereof.

In accordance with another aspect of the present invention, provided is a method of forming a thin film, the method including injecting a step coverage improver represented by Chemical Formula 1 below into a chamber to shield a surface of a loaded substrate.

### [Chemical Formula 1]

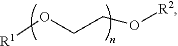

wherein R1 and R2 are independently H or an alkyl group having 1 to 5 carbon atoms, and n is an integer from 2 to 4.

A precursor compound used in the method of forming a thin film may be a compound represented by Chemical Formula 2 below.

### [Chemical Formula 2]

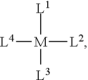

wherein M includes one or more selected from Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd; and L1, L2, L3, and L4 are —H, —X, —R, —OR, —NR2, or Cp (cyclopentadiene), and are the same or different, wherein —X is F, Cl, Br, or I; —R is linear or cyclic C1-C10 alkyl, C1-C10 alkene, or C1-C10 alkane; and L1, L2, L3, and L4 are formed from 2 to 6 depending on an oxidation number of a central metal (M).

For example, when the central metal is divalent, L1 and L2 may be attached to the central metal as ligands. When the central metal is hexavalent, L1, L2, L3, L4, L5, and L6 may be attached to the central metal. The ligands corresponding to L1 to L6 may be the same or different.

In Chemical Formula 2, L1, L2, L3, and L4 may be —H, or —R, and may be the same or different. Here, —R may be linear or circular C1-C10 alkyl, C1-C10 alkene, or C1-C10 alkane.

In Chemical Formula 2, L1, L2, L3, and L4 may be —H, —OR, —NR2, or Cp (cyclopentadiene), and may be the same or different. Here, —R may be H, C1-C10 alkyl, C1-C10 alkene, C1-C10 alkane, iPr, or TBu.

In Chemical Formula 2, L1, L2, L3, and L4 may be —H or —X, and may be the same or different. Here, —X may be F, Cl, Br, or I.

In accordance with still another aspect of the present invention, provided is a method of forming a thin film, the method including:
i) vaporizing the step coverage improver to form a shielded area on a surface of a substrate loaded into a chamber;
ii) performing 1st purging inside the chamber with a purge gas;
iii) vaporizing a precursor compound and adsorbing the precursor compound onto an area outside the shielded area;
iv) performing 2nd purging inside the chamber with a purge gas;
v) supplying a reaction gas inside the chamber; and
vi) performing 3rd purging inside the chamber with a purge gas.

The precursor compound may be a molecule composed of one or more selected from the group consisting of Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd, and may be a precursor having a vapor pressure of greater than 0.01 mTorr and 100 Torr or less at 25° C.

The chamber may be an ALD chamber, a CVD chamber, a PEALD chamber, or a PECVD chamber.

The step coverage improver or the precursor compound may be vaporized, injected, and then subjected to plasma post-treatment.

In steps i) and iv), an amount of the purge gas injected into the chamber at each step may be 10 to 100,000 times a volume of the introduced step coverage improver.

The reaction gas may be an oxidizing agent, a nitriding agent, or a reducing agent, and the reaction gas, the step coverage improver, and the precursor compound may be transferred into the chamber by a VFC, DLI, or LDS method.

The thin film may be a silicon nitride film, a silicon oxide film, a titanium nitride film, a titanium oxide film, a tungsten nitride film, a molybdenum nitride film, a hafnium oxide film, a zirconium oxide film, a tungsten oxide film, or an aluminum oxide film.

The substrate loaded into the chamber may be heated to 100 to 800° C., and the ratio of amount (mg/cycle) of the step coverage improver and the precursor compound fed into the chamber may be 1:1 to 1:20.

In accordance with still another aspect of the present invention, provided is a semiconductor substrate including the thin film manufactured by the above-described method of forming a thin film.

The thin film may have a multilayer structure of two or more layers.

In accordance with yet another aspect of the present invention, provided is a semiconductor device including the above-described semiconductor substrate.

The semiconductor substrate may be low resistive metal gate interconnects, a high aspect ratio 3D metal-insulator-metal capacitor, a DRAM trench capacitor, 3D Gate-All-Around (GAA), or a 3D NAND flash memory.

### Advantageous Effects

According to the present invention, the present invention has an effect of providing a step coverage improver that improves step coverage even when forming a thin film on a substrate with a complex structure under high-temperature conditions by effectively shielding adsorption on the surface of the substrate to improve reaction speed and reduce a thin film growth rate appropriately.

In addition, by more effectively reducing process by-products during thin film formation, corrosion and deterioration can be prevented, film quality can be improved, the crystallinity of a thin film can be improved, and the electrical properties of the thin film can be improved.

In addition, when forming a thin film, process by-products can be reduced, and step coverage and thin film density can be improved. In addition, a method of forming a thin film and a semiconductor substrate fabricated by the method can be provided.

### DESCRIPTION OF DRAWINGS

FIG. 1 is a schematic diagram showing a deposition process sequence according to the present invention, focusing on one cycle.

FIG. 2 is a diagram showing the SIMC C analysis results measured in Example 1 according to the present invention and Comparative Examples 1, 3, and 4, respectively.

FIG. 3 includes TEM images showing deposition thicknesses at the upper portion (100 nm below the top) and lower portion (100 nm above the bottom) of the cross-section of an oxide film deposited without using a step coverage improver according to Comparative Example 1 and deposition thicknesses at the upper portion (100 nm below the top) and lower portion (100 nm above the bottom) of the cross-section of an oxide film deposited using a step coverage improver.

FIG. 4 includes TEM images showing deposition thicknesses at the upper portion (100 nm below the top) and lower portion (100 nm above the bottom) of the cross-section of an oxide film deposited using a step coverage improver according to Example 1 and deposition thicknesses at the upper portion (100 nm below the top) and lower portion (100 nm above the bottom) of the cross-section of an oxide film deposited using a step coverage improver.

### BEST MODE

Hereinafter, a step coverage improver of the present invention, a method of forming a thin film using the step coverage improver, and a semiconductor substrate including the thin film will be described in detail.

In the present disclosure, unless otherwise specified, the term “step coverage improver” means improving step coverage by reducing, inhibiting, or blocking the adsorption of a precursor compound for forming a thin film onto a substrate and the adsorption of process by-products onto the substrate.

The present inventors confirmed that, by providing a compound with a predetermined structure as a step coverage improver of a deposition film formed on a substrate loaded inside a chamber, by forming a deposition layer with a uniform thickness due to the difference in adsorption distribution of the compound as a shielded area that does not remain in a thin film, as a relatively coarse thin film was formed, the growth rate of a thin film formed at the same time was greatly reduced, so that even when applied to a substrate having a complex structure, the uniformity of the thin film was secured, and the step coverage was greatly improved. In particular, thin-thickness deposition was possible, and the remaining O, Si, metal, and metal oxides as process by-products and carbon residues, which were difficult to reduce in the past, were reduced. Based on these results, the present inventors conducted further studies on the step coverage improver to complete the present invention.

For example, the thin film may be provided with one or more precursors selected from the group consisting of Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd, may improve the step coverage of an oxide film, nitride film, or metal film. In this case, the effects desired in the present invention may be sufficiently achieved.

As a specific example, the thin film may have a film composition of a silicon nitride film, a silicon oxide film, a titanium nitride film, a titanium oxide film, a tungsten nitride film, a molybdenum nitride film, a hafnium oxide film, a zirconium oxide film, a tungsten oxide film, or an aluminum oxide film.

The thin film may contain the aforementioned film composition alone or in a selective area, but is not limited thereto, and also includes SiH and SiOH.

In addition to a commonly used diffusion barrier film, the thin film may be uses as an etching stop film, electrode film, dielectric film, gate insulating film, block oxide film, or charge trap to improve step coverage during the formation process thereof, and may be used in semiconductor devices.

In the present invention, the precursor compound used in the formation of the thin film is a molecule having Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, or Nd as a central metal atom (M) and one or more ligands of C, N, O, H, and X (halogen). For a precursor having a vapor pressure of 1 mTorr to 100 Torr at 25° C., the shielding effect may be maximized by using the step coverage improver described later.

For example, a compound represented by Chemical Formula 2 below may be used as the precursor compound.

### [Chemical Formula 2]

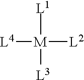

In Chemical Formula 2, M includes one or more selected from Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd; and L1, L2, L3, and L4 are —H, —X, —R, —OR, —NR2, or Cp (cyclopentadiene), and are the same or different. Here, —X is F, Cl, Br, or I; —R is linear or circular C1-C10 alkyl, C1-C10 alkene, or C1-C10 alkane; and the ligands L1, L2, L3, and L4 may be formed from 2 to 6 depending on the oxidation number of the central metal.

For example, when the central metal is divalent, L1 and L2 may be attached to the central metal as ligands. When the central metal is hexavalent, L1, L2, L3, L4, L5, and L6 may be attached to the central metal. The ligands corresponding to L1 to L6 may be the same or different.

In Chemical Formula 2, M is hafnium (Hf), silicon (Si), zirconium (Zr), or aluminum (Al), preferably hafnium (Hf) or silicon (Si). In this case, the effect of reducing process by-products and the effect of improving thin film density may be increased, and step coverage and the electrical properties, insulating properties, and dielectric properties of the thin film may be excellent.

L1, L2, L3, and L4 are —H, or —R, and are the same or different. Here, —R may be C1-C10 alkyl, C1-C10 alkene, or C1-C10 alkane and may have a linear or cyclic structure.

In addition, L1, L2, L3, and L4 are —H, —OR, —NR2, or Cp (cyclopentadiene), and may be the same or different. Here, —R may be H, C1-C10 alkyl, C1-C10 alkene, C1-C10 alkane, iPr, or tBu.

In addition, in Chemical Formula 2, L1, L2, L3, and L4 may be —H or —X, and may be the same or different. Here, —X may be F, Cl, Br, or I.

Specifically, examples of the hafnium precursor compound may include tris(dimethylamido)cyclopentadienyl hafnium of CpHf(NMe₂)₃ and (methyl-3-cyclopentadienylpropylamino)bis(dimethylamino)hafnium of Cp(CH)₃NM₃Hf(NMe₂)₂.

In addition, examples of the silicon precursor compound may include one or more selected from SiH₄, SiHCl₃, SiH₂Cl₂, SiCl₄, Si₂Cl₆Si₃Cl₈, Si₄Cl₁₀, SiH₂[NH(C₄H₉)]₂, Si₂(NHC₂H₅)₄, Si₃NH₄(CH₃)₃, SiH₃[N(CH₃)₂], SiH₂[N(CH₃)₂]₂, SiH[N(CH₃)₂]₃, and Si[N(CH₃)₂]₄.

In addition, as the titanium precursor compound, titanium tetrachloride (TiCl₄), tetrakis dimethylamino titanium (TDMAT), and Ti(CpMe₅) (OMe)₃ may be used.

The step coverage improver of the present invention has a long-chain structure and may uniformly provide substrate adsorption of a precursor compound by being adsorbed on the surface of a substrate prior to adsorption of a precursor compound to be adsorbed onto the substrate. That is, it is desirable to use a compound that may provide an area (hereinafter, also referred to as a shielded area) to shield the adsorption of the precursor compound adsorbed on the substrate.

For example, the shielded area may be formed on the entire substrate or a portion of the substrate on which the thin film is formed.

In addition, when a total area of the substrate is 100%, a shielded area may occupy 10 to 95%, as a specific example, 15 to 90%, preferably 20 to 85%, more preferably 30 to 80%, still more preferably 40 to 75%, still more preferably 40 to 70% of a total area of the entire substrate or a portion of the substrate, and an unshielded area may occupy the remaining area.

In addition, when a total area of the substrate is 100%, a first shielded area may occupy 10 to 95%, as a specific example, 15 to 90%, preferably 20 to 85%, more preferably 30 to 80%, still more preferably 40 to 75%, still more preferably 40 to 70% of a total area of the entire substrate or a portion of the substrate, a second shielded area may occupy 10 to 95%, as a specific example, 15 to 90%, preferably 20 to 85%, more preferably 30 to 80%, still more preferably 40 to 75%, still more preferably 40 to 70% of the remaining area, and an unshielded area may occupy the remaining area.

The step coverage improver may provide the above-described shielded area on the substrate surface to provide the above-described thin film.

The step coverage improver may have two or more nitrogen (N), oxygen (O), phosphorus (P), or sulfur (S) elements, and may include a linear or cyclic saturated or unsaturated hydrocarbon having 3 to 15 carbon atoms. In this case, by forming a shielded area that does not remain in a thin film during thin film formation, a relatively coarse thin film may be formed and side reactions may be suppressed. In addition, by controlling the thin film growth rate, process by-products within the thin film may be reduced, thereby reducing corrosion and deterioration. In addition, the crystallinity of the thin film may be improved, and a stoichiometric oxidation state may be reached when a metal oxide film is formed. In addition, even when a thin film is formed on a substrate having a complex structure, step coverage and the thickness uniformity of a thin film may be greatly improved.

As a specific example, the step coverage improver has a structure containing nitrogen (N), oxygen (O), phosphorus (P), or sulfur (S) at each terminal of a central carbon atom connected by a double bond to oxygen. Thus, the effect of reducing process by-products and the effect of improving thin film density may be increased, and step coverage and the electrical properties of the thin film may be excellent.

As a specific example, the step coverage improver may include one or more selected from compounds represented by Chemical Formula 1 below. In this case, by forming a shielded area that does not remain in a thin film during thin film formation, a relatively coarse thin film may be formed and side reactions may be suppressed. In addition, by controlling the thin film growth rate, process by-products within the thin film may be reduced, thereby reducing corrosion and deterioration. In addition, the crystallinity of a thin film may be improved. In addition, even when a thin film is formed on a substrate having a complex structure, step coverage and the thickness uniformity of a thin film may be greatly improved.

### [Chemical Formula 1]

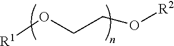

In Chemical Formula 1, R1 and R2 are independently H or an alkyl group having 1 to 5 carbon atoms, and n is an integer from 2 to 4.

In Chemical Formula 1, R1 and R2 are an alkyl group having 1 to 5 carbon atoms, preferably an alkyl group having 2 to 4 carbon atoms. In this case, the effect of reducing process by-products and the effect of improving thin film density may be increased, and step coverage and the electrical properties, insulating properties, and dielectric properties of the thin film may be excellent.

In Chemical Formula 1, n is an integer from 2 to 4, preferably an integer from 2 to 3. In this case, the effect of reducing process by-products and the effect of improving thin film density may be increased, and step coverage and the electrical properties, insulating properties, and dielectric properties of the thin film may be excellent.

The step coverage improver, preferably the compound represented by Chemical Formula 1 may have a deposition rate reduction rate of 30% or more, as a specific example, 33% or more, preferably 35% or more as calculated by Equation 1 below. In this case, by forming a shielded area that does not remain in a thin film by the step coverage improver having the above-described structure, as a relatively coarse thin film is formed, the growth rate of a thin film formed at the same time is greatly reduced, so that even when applied to a substrate having a complex structure, the uniformity of the thin film may be secured, and the step coverage may be greatly improved. In particular, deposition in a thin thickness is possible, and the remaining amounts of O, Si, metals, and metal oxides remaining as process by-products may be improved. In addition, even the remaining amount of carbon, which was difficult to reduce in the past, may be improved.

Deposition rate reduction rate=[{(DRn)−(DRw)}/(DRn)]×100 [Equation 1]

In Equation 1, DRn is the depth rate measured on the manufactured thin film without adding the step coverage improver, and DRw is the depth rate measured on the manufactured thin film with the addition of the step coverage improver. Here, the depth rate is measured at room temperature and pressure using an ellipsometer for a thin film with a thickness of 3 to 30 nm, and the unit is Å/cycle.

In Equation 1, the thin film growth rate per cycle when the step coverage improver is used and when the step coverage improver is not used means the thin film deposition thickness (Å/cycle) per each cycle, that is, the deposition rate. For example, the deposition rate may be obtained as an average deposition rate calculated by measuring the final thickness of a thin film with a thickness of 3 to 30 nm under room temperature and pressure conditions using an ellipsometer, and then dividing the final thickness by the total number of cycles.

In Equation 1, “when the step coverage improver is not used” means that a thin film is manufactured by adsorbing only a precursor compound on a substrate in a thin film deposition process. As a specific example, in the thin film forming method, the above case refers to a case where a thin film is formed by omitting a step of adsorbing a step coverage improver and a step of purging an unadsorbed step coverage improver.

For example, the step coverage improver may be a compound having a refractive index of 1.38 or more, as a specific example, 1.38 to 1.5, or 1.38 to 1.45, preferably 1.39 to 1.44.

In this case, the step coverage improver having the above-described structure on the substrate forms a shielded area that does not remain in the thin film. Thus, the deposition rate of the thin film may be reduced, and the thin film growth rate may be appropriately reduced. In addition, even when forming a thin film on a substrate with a complex structure, step coverage and the thickness uniformity of a thin film may be greatly improved. In addition to a thin film precursor, the surface of the substrate may be effectively protected by preventing the adsorption of process by-products, and process by-products may be effectively removed.

In particular, as a relatively coarse thin film is formed, the growth rate of a thin film formed at the same time is greatly reduced, so that even when applied to a substrate having a complex structure, the uniformity of the thin film may be secured, and the step coverage may be greatly improved. In particular, deposition in a thin thickness is possible, and the remaining amounts of O, Si, metals, and metal oxides remaining as process by-products may be improved. In addition, even the remaining amount of carbon, which was difficult to reduce in the past, may be improved.

The compound represented by Chemical Formula 1 may include compounds represented by Chemical Formulas 1-1 to 1-6. In this case, by providing a deposition layer with a uniform thickness as a shielded area on a substrate due to the difference in adsorption distribution on the substrate, the growth rate of a thin film may be effectively controlled, process by-products may be effectively removed, and step coverage and film quality may be greatly improved.

### [Chemical Formulas 1-1 to 1-6]

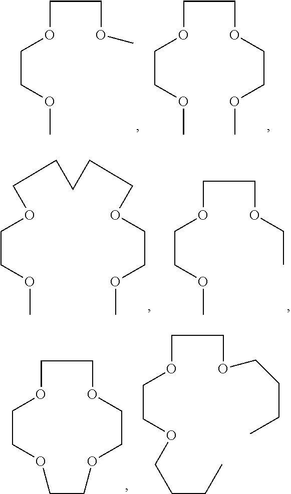

The step coverage improver may provide the above-described shielded area for thin films.

The shielded area for thin films does not remain on the thin film.

At this time, unless otherwise specified, non-residue refers to a case where the content of C element is less than 0.1 atom %, the content of Si element is less than 0.1 atom %, the content of N element is less than 0.1 atom %, and the content of halogen element is less than 0.1 atom % when analyzed by XPS. More preferably, in the secondary-ion mass spectrometry (SIMS) measurement method or X-ray photoelectron spectroscopy (XPS) measurement method, in which measurements are performed in the depth direction of a substrate, considering the increase/decrease rate of C, N, Si, and halogen impurities before and after using the step coverage improver under the same deposition conditions, it is desirable that the increase/decrease rate of the signal sensitivity (intensity) of each element type does not exceed 5%.

For example, the thin film may include a halogen compound in an amount of 100 ppm or less.

The thin film may be used as an etching stop film, an electrode film, a dielectric film, a gate insulating film, a block oxide film, or a charge trap, without being limited thereto.

The step coverage improver may be preferably a compound having a purity of 99.9% or more, 99.95% or more, or 99.99% or more. For reference, when a compound having a purity of less than 99% is used, impurities may remain in a thin film or cause side reactions with precursors or reactants. Accordingly, it is desirable to use a material having a purity of 99% or more.

The step coverage improver is preferably used in the atomic layer deposition (ALD) process. In this case, the surface of a substrate may be effectively protected and process by-products may be effectively removed without interfering with the adsorption of a precursor compound.

The step coverage improver may preferably be liquid at room temperature (22° C.), and may have a density of 0.8 to 2.5 g/cm³ or 0.8 to 1.5 g/cm³ and a vapor pressure (20° C.) of 0.1 to 300 mmHg or 1 to 300 mmHg. Within this range, a shielded area may be effectively formed, and the step coverage and the thickness uniformity and film quality of a thin film may be greatly improved.

More preferably, the step coverage improver may have a density of 0.75 to 2.0 g/cm³ or 0.8 to 1.3 g/cm³ and a vapor pressure (20° C.) of 1 to 260 mmHg. Within this range, a shielded area may be effectively formed, and the step coverage and the thickness uniformity and film quality of a thin film may be greatly improved.

The method of forming a thin film according to the present invention includes a step of injecting the step coverage improver represented by Chemical Formula 1 below into the chamber to shield the surface of a loaded substrate. In this case, by forming a deposition layer with a uniform thickness as a shielded area on the substrate due to the difference in adsorption distribution on the substrate, the deposition rate of a thin film may be reduced, and the thin film growth rate may be appropriately reduced. Thus, even when forming a thin film on a substrate with a complex structure, step coverage and the thickness uniformity of a thin film may be greatly improved.

### [Chemical Formula 1]

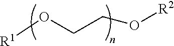

In Chemical Formula 1, R1 and R2 are independently H or an alkyl group having 1 to 5 carbon atoms, and n is an integer from 2 to 4.

In the step of shielding the step coverage improver on the substrate surface, the feeding time (sec) of the step coverage improver on the substrate surface may be preferably 0.01 to 10 seconds, more preferably 0.02 to 8 seconds, still more preferably 0.04 to 6 seconds, still more preferably 0.05 to 5 seconds per cycle. Within this range, thin film growth rate may be reduced, and step coverage and economics may be excellent.

In the present disclosure, the feeding time of the precursor compound is based on a flow rate of 0.1 to 500 mg/cycle at a chamber volume of 15 to 20 L, more specifically based on a flow rate of 0.8 to 200 mg/cycle at a chamber volume of 18 L.

As a preferred example, the method of forming a thin film may include step i) of vaporizing a step coverage improver to shield the surface of a substrate loaded in a chamber; step ii) of performing 1st purging inside the chamber with a purge gas; step iii) of vaporizing a precursor compound and adsorbing the precursor compound onto the surface of the substrate loaded in the chamber; step iv) of performing 2nd purging inside the chamber with a purge gas; step v) of supplying a reaction gas inside the chamber; and step vi) of performing 3rd purging inside the chamber with a purge gas.

At this time, steps i) to vi) may be repeated as a unit cycle until a thin film of the desired thickness is obtained. In this way, in one cycle, when the step coverage improver of the present invention is injected before the precursor compound and is absorbed into the substrate, even when deposition is performed at high temperatures, the thin film growth rate may be appropriately reduced, process by-products may be effectively removed, the resistivity of the thin film may be reduced, and the step coverage may be significantly improved.

As a preferred example, in the method of forming a thin film according to the present invention, in one cycle, by introducing the step coverage improver of the present invention before the precursor compound, the surface of the substrate may be activated, and then the precursor compound may be introduced to adsorb the precursor compound onto the substrate. In this case, even when a thin film is deposited at high temperatures, by providing a deposition layer with a uniform thickness as a shielded area on a substrate due to the difference in adsorption distribution on the substrate, the thin film growth rate may be appropriately reduced, process by-products may be significantly reduced, and step coverage may be significantly improved. In addition, the resistivity of the thin film may decrease due to an increase in the crystallinity of the thin film. In addition, even when applied to semiconductor devices with a large aspect ratio, the thickness uniformity of the thin film is greatly improved, thereby ensuring the reliability of the semiconductor devices.

For example, in the method of forming a thin film, when the step coverage improver is deposited before or after the deposition of the precursor compound, depending on the needs, the unit cycle may be repeated 1 to 99,999 times, preferably 10 to 10,000 times, more preferably 50 to 5,000 times, still more preferably 100 to 2,000 times. Within this range, the desired thickness of the thin film may be obtained, and the effects intended for the present invention may be sufficiently achieved.

The precursor compound is a compound having Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, or Nd as a central metal atom and one or more ligands selected from C, N, O, and H. For a precursor having a vapor pressure of 1 mTorr to 100 Torr at 25° C., the effect of forming a shielded area by the above-described step coverage improver may be maximized.

Any compound known in the art may be used as the precursor compound without any particular limitation. For example, a compound containing a cyclopentadiene (Cp) group or a halogen group may be used as the precursor compound.

Specifically, examples of the hafnium precursor compound may include tris(dimethylamido)cyclopentadienyl hafnium of CpHf(NMe₂)₃ and (methyl-3-cyclopentadienylpropylamino)bis(dimethylamino)hafnium of Cp(CH)₃NM₃Hf(NMe₂)₂.

In addition, examples of the silicon precursor compound may include one or more selected from SiH₄, SiHCl₃, SiH₂Cl₂, SiCl₄, Si₂Cl₆Si₃Cl₈, Si₄Cl₁₀, SiH₂[NH(C₄H₉)]₂, Si₂(NHC₂H₅)₄, Si₃NH₄(CH₃)₃, SiH₃[N(CH₃)₂], SiH₂[N(CH₃)₂]₂, SiH[N(CH₃)₂]₃, and Si[N(CH₃)₂]₄.

In addition, examples of the titanium precursor compound may include titanium tetrachloride (TiCl₄), tetrakis dimethylamino titanium (TDMAT), and Ti(CpMe₅)(OMe)₃.

In the present invention, for example, the chamber may be an ALD chamber, a CVD chamber, a PEALD chamber, or a PECVD chamber.

In the present invention, the step coverage improver or precursor compound may be vaporized, injected, and then subjected to plasma post-treatment. In this case, the growth rate of thin film may be improved and process by-products may be reduced.

When the step coverage improver is first adsorbed on the substrate and then the precursor compound is adsorbed, the amount of purge gas injected into the chamber during the step of purging the unadsorbed step coverage improver is not particularly limited as long as the amount is sufficient to remove the unadsorbed step coverage improver. For example, the amount of purge gas may be 10 to 100,000 times, preferably 50 to 50,000 times, more preferably 100 to 10,000 times. Within this range, by sufficiently removing the unadsorbed step coverage improver, a thin film may be formed evenly and deterioration of film quality may be prevented. Here, the input amounts of the purge gas and step coverage improver are each based on one cycle, and the volume of the step coverage improver means the volume of the vaporized step coverage improver.

As a specific example, in the step of injecting the step coverage improver in an injection amount of 200 sccm and purging the unadsorbed step coverage improver, when a purge gas is injected at a flow rate of 5000 mL/min, the injection amount of the purge gas is 25 times the injection amount of the step coverage improver.

In addition, in the step of purging the unadsorbed precursor compound, the amount of purge gas injected into the chamber is not particularly limited as long as the amount is sufficient to remove the unadsorbed precursor compound. For example, the amount may be 10 to 10,000 times, preferably 50 to 50,000 times, more preferably 100 to 10,000 times the volume of the precursor compound injected into the chamber. Within this range, by sufficiently removing the unadsorbed precursor compound, a thin film may be formed evenly and deterioration of film quality may be prevented. Here, the input amounts of the purge gas and precursor compound are each based on one cycle, and the volume of the precursor compound refers to the volume of the vaporized precursor compound vapor.

In addition, in the purging step performed immediately after the reaction gas supply step, the amount of purge gas introduced into the chamber may be, for example, 10 to 10,000 times, preferably 50 to 50,000 times, more preferably 100 to 10,000 times the volume of reaction gas introduced into the chamber. Within this range, the desired effects may be sufficiently achieved. Here, the input amounts of purge gas and reaction gas are based on one cycle.

The step coverage improver and the precursor compound may be transported into the chamber preferably by a VFC, DLI, or LDS method, more preferably an LDS method.

For example, the substrate loaded into the chamber may be heated to 100 to 650° C., as a specific example, 150 to 550° C. The step coverage improver or the precursor compound may be injected onto the substrate in an unheated or heated state, or may be injected unheated and then heated during the deposition process, depending on the deposition efficiency. For example, the step coverage improver or the precursor compound may be injected onto the substrate at 100 to 650° C. for 1 to 20 seconds.

The ratio of amount (mg/cycle) of the precursor compound and the step coverage improver fed into the chamber may be preferably 1:1.5 to 1:20, more preferably 1:2 to 1:15, still more preferably 1:2 to 1:12, still more preferably 1:2.5 to 1:10. Within this range, step coverage may be improved, and process by-products may be greatly reduced.

For example, in the method of forming a thin film, when the step coverage improver is used, the deposition rate reduction rate may be 30% or more, as a specific example, 33% or more, preferably 35% or more as calculated by Equation 1 below. In this case, by forming a deposition layer with a uniform thickness due to the difference in adsorption distribution of the step coverage improver having the above-described structure as a shielded area that does not remain in the thin film, as a relatively coarse thin film is formed, the growth rate of a thin film formed at the same time is greatly reduced, so that even when applied to a substrate having a complex structure, the uniformity of the thin film may be secured, and the step coverage may be greatly improved. In particular, deposition in a thin thickness is possible, and the remaining amounts of O, Si, metals, and metal oxides remaining as process by-products may be improved. In addition, even the remaining amount of carbon, which was difficult to reduce in the past, may be improved.

Deposition rate reduction rate=[{(DRᵢ)−(DR_{f})}/(DRᵢ)]×100 [Equation 1]

In Equation 1, deposition rate (DR, Å/cycle) is the speed at which a thin film is deposited. In the deposition of a thin film formed from a precursor and a reactant, DRᵢ (initial deposition rate) is the deposition rate of the thin film formed without adding a step coverage improver. DR_{f} (final deposition rate) is the deposition rate of the thin film formed by adding the step coverage improver during the above process. Here, the deposition rate (DR) is a value measured at room temperature and pressure using an ellipsometer for a thin film with a thickness of 3 to 30 nm, and is expressed in a unit of Å/cycle.

In the method of forming a thin film, the residual carbon impurity intensity (c/s) in the thin film may be preferably 100,000 or less, more preferably 70,000 or less, still more preferably 50,000 or less, still more preferably 10,000 or less, as a preferred example, 5,000 or less, still more preferably 500 to 3,000, still more preferably 100 to 1,000 as measured using a thin film having a thickness of 100 Å according to SIMS. Within this range, corrosion and deterioration may be effectively prevented.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

The atomic layer deposition (ALD) process is very advantageous in manufacturing integrated circuits (ICs) that require a high aspect ratio. In particular, the ALD process has advantages such as excellent conformality, uniformity, and precise thickness control due to the self-limiting thin film growth mechanism.

For example, the method of forming a thin film may be performed at a deposition temperature of 50 to 800° C., preferably 300 to 700° C., more preferably 400 to 650° C., still more preferably 400 to 600° C. Within this range, a thin film with excellent film quality may be grown while implementing ALD process characteristics.

For example, the method of forming a thin film may be performed at a deposition pressure of 0.01 to 20 Torr, preferably 0.1 to 20 Torr, more preferably 0.1 to 10 Torr, most preferably 0.3 to 7 Torr. Within this range, a thin film having a uniform thickness may be obtained.

In the present disclosure, the deposition temperature and the deposition pressure may be measured as temperature and pressure formed within the deposition chamber, or as temperature and pressure applied to the substrate within the deposition chamber.

The method of forming a thin film may include preferably a step of increasing the temperature inside the chamber to the deposition temperature before introducing the step coverage improver into the chamber; and/or a step of purging by injecting inert gas into the chamber before introducing the step coverage improver into the chamber.

In addition, as a thin film manufacturing device capable of implementing the thin film manufacturing method, the present invention may include a thin film manufacturing device including an ALD chamber, a first vaporizer for vaporizing a step coverage improver, a first transport means for transporting the vaporized step coverage improver into the ALD chamber, a second vaporizer for vaporizing a thin film precursor, and a second transport means for transporting the vaporized thin film precursor into the ALD chamber. Here, vaporizers and transport means commonly used in the technical field to which the present invention pertains may be used in the present invention without particular limitation.

As a specific example, the method of forming a thin film is explained. First, a substrate on which a thin film is to be formed is placed in a deposition chamber capable of atomic layer deposition.

The substrate may include a semiconductor substrate, such as a silicon substrate or a silicon oxide substrate.

The substrate may further have a conductive layer or an insulating layer formed on the upper portion thereof.

To deposit a thin film on the substrate positioned in the deposition chamber, the above-described step coverage improver, a precursor compound, or a mixture of the precursor compound and a non-polar solvent is prepared.

Then, the prepared step coverage improver is injected into a vaporizer, is transformed into a vapor phase, is transferred into a deposition chamber, and is adsorbed on a substrate. Then, purging is performed to remove the unadsorbed step coverage improver.

Next, the prepared precursor compound or mixture of the precursor compound and a non-polar solvent (composition for forming a thin film) is injected into the vaporizer, is transformed into a vapor phase, is transferred into the deposition chamber, and is adsorbed on the substrate. Then, the unadsorbed precursor compound/composition for forming a thin film is purged.

In the present disclosure, when necessary, a process of removing the unadsorbed step coverage improver by purging after adsorbing the step coverage improver on the substrate; and a process of adsorbing a precursor compound onto the substrate and purging to remove the unadsorbed precursor compound may be performed in reverse order.

In the present disclosure, for example, the step coverage improver and the precursor compound (composition for forming a thin film) may be delivered into the deposition chamber by vapor flow control (VFC) using mass flow control (MFC) or a liquid delivery system (LDS) using liquid mass flow control (LMFC), preferably an LDS method.

At this time, as a carrier gas or dilution gas for moving the step coverage improver and the precursor compound onto the substrate, a mixed gas containing one or more selected from the group consisting of argon (Ar), nitrogen (N₂), helium (He), neon (Ne), xenon (Xe), and krypton (Kr) may be used, but the present invention is not limited thereto.

In the present disclosure, for example, an inert gas, preferably the carrier gas or dilution gas may be used as the purge gas.

Next, a reaction gas is supplied. Any reaction gas commonly used in the technical field to which the present invention pertains may be used as the reaction gas without particular limitation. Preferably, the reaction gas may include a nitriding agent, n oxidizing agent, or a reducing agent. The nitriding agent and the precursor compound adsorbed on the substrate react to form a nitride film, the oxidizing agent and the precursor compound react to form an oxide film, and the reducing agent and the precursor compound react to form a metal film.

Preferably, the nitriding agent may be nitrogen gas (N₂), hydrazine gas (N₂H₄), or a mixture of nitrogen gas and hydrogen gas.

Preferably, the oxidizing agent may be ozone gas (O₃), oxygen gas (O₂), water vapor (H₂O), hydrogen peroxide (H₂O₂), nitric oxide (NO₂, N₂O), or a mixture thereof.

Preferably, the reducing agent may be hydrogen gas (H₂), acetic acid gas (HCOOH), ammonia gas (NH₃), or a mixture thereof.

Next, unreacted residual reaction gas is purged using an inert gas. Accordingly, in addition to excess reaction gas, generated byproducts may also be removed.

As described above, in the method of forming a thin film, for example, a step of activating the step coverage improver on the substrate, a step of shielding the step coverage improver on the substrate, a step of purging the unadsorbed step coverage improver, a step of adsorbing a precursor compound/composition for forming a thin film on the substrate, a step of purging the unadsorbed precursor compound/composition for forming a thin film, a step of supplying a reaction gas, and a step of purging the residual reaction gas may be set as a unit cycle. To form a thin film of desired thickness, the unit cycle may be repeated.

As another example, in the method of forming a thin film, a step of adsorbing a precursor compound/composition for forming a thin film on the substrate, a step of purging the unadsorbed precursor compound/composition for forming a thin film, a step of adsorbing the step coverage improver onto the substrate, a step of purging the unadsorbed step coverage improver, a step of supplying a reaction gas, and a step of purging the residual reaction gas may be set as a unit cycle. To form a thin film of desired thickness, the unit cycle may be repeated.

For example, the unit cycle may be repeated 1 to 99,999 times, preferably 10 to 1,000 times, more preferably 50 to 5,000 times, still more preferably 100 to 2,000 times. Within this range, the desired thin film properties may be well expressed.

In addition, the present invention provides a semiconductor substrate, and the semiconductor substrate is fabricated by the thin film formation method. In this case, the step coverage and thickness uniformity of a thin film may be excellent, and density and electrical properties may be excellent.

For example, the thin film may have a thickness of 0.1 to 20 nm, preferably 0.5 to 20 nm, more preferably 1.5 to 15 nm, still more preferably 2 to 10 nm. Within this range, thin film properties may be excellent.

The thin film may have a carbon impurity content of preferably 5,000 counts/sec or less or 1 to 3,000 counts/sec, still more preferably 10 to 1,000 counts/sec, still more preferably 50 to 500 counts/sec. Within this range, thin film properties may be excellent, and thin film growth rate may be reduced.

For example, the thin film may have a step coverage of 90% or more, preferably 92% or more, more preferably 95% or more. Within this range, since even a thin film of complex structure may be easily deposited on a substrate, the thin film may be applied to next-generation semiconductor devices.

The manufactured thin film may have a thickness of preferably 20 nm or less, a dielectric constant of 5 to 29 based on a thin film thickness of 10 nm, a carbon, nitrogen, and halogen content of 5,000 counts/sec or less, and a step coverage of 90% or more. Within this range, the thin film may have excellent performance as a dielectric film or blocking film, without being limited thereto.

For example, when necessary, the thin film may have a multilayer structure of two or more layers, preferably a multilayer structure of two or three layers. As a specific example, the multilayer film with a two-layer structure may have a lower layer-middle layer structure, and the multilayer film with a three-layer structure may have a lower layer-middle layer-upper layer structure.

For example, the lower layer may be formed of one or more selected from the group consisting of Si, SiO₂, MgO, Al₂O₃, CaO, ZrSiO₄, ZrO₂, HfSiO₄, Y₂O₃, HfO₂, LaLuO₂, Si₃N₄, SrO, La₂O₃, Ta₂O₅, BaO, and TiO₂.

For example, the middle layer may be formed of TiₓN_{y}, preferably TN.

For example, the upper layer may be formed of one or more selected from the group consisting of W and Mo.

Hereinafter, preferred examples and drawings are presented to help understand the present invention, but the following examples and drawings are only illustrative of the present invention, and it is obvious to those skilled in the art that various changes and modifications are possible within the scope and technical idea of the present invention. Such changes and modifications fall within the scope of the appended patent claims.

### EXAMPLES

### Example 1, Comparative Examples 1 to 5

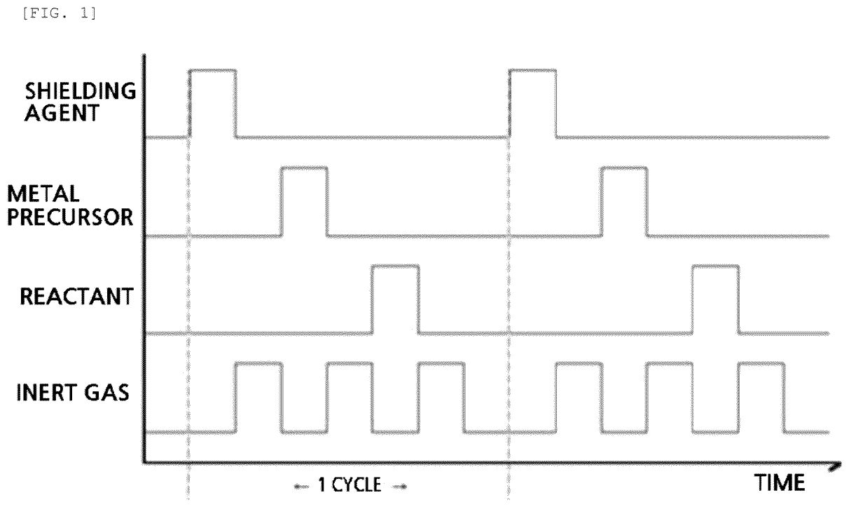

An ALD deposition process was performed according to the process shown in FIG. 1 below using the components shown in Table 1 below.

FIG. 1 below is a schematic diagram showing a deposition process sequence according to the present invention, focusing on one cycle.

Specifically, as the step coverage improver, a compound represented by Chemical Formula 1-6 below, a compound represented by Chemical Formula 1-7 below, a compound represented by Chemical Formula 1-8 below, a compound represented by Chemical Formula 1-9 below, and a compound represented by Chemical Formula 1-10 below were prepared.

### [Chemical Formula 1-6]

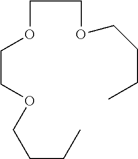

### [Chemical Formula 1-7]

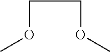

### [Chemical Formula 1-8]

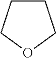

### [Chemical Formula 1-9]

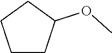

### [Chemical Formula 1-10]

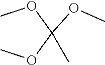

In addition, as the precursor, tris(dimethylamido)cyclopentadienyl hafnium of CpHf(NMe₂)₃) was prepared (Indicated as CpHf in Table 1 below).

Argon was introduced into the chamber at a rate of 5000 ml/min, and a vacuum pump was used to create a thin, inert atmosphere by maintaining the pressure inside the chamber at 1.5 Torr.

The step coverage improver shown in Table 1 below was placed in a canister and the partial pressure and temperature were adjusted to achieve the injection amount (mg/cycle). Then, the step coverage improver was applied into a substrate loaded into the chamber for 1 second, and the chamber was purged for 10 seconds.

Next, the precursor compound was placed in the canister and injected into the deposition chamber through a vapor flow controller (VFC) as shown in Table 1, and the chamber was purged for 10 seconds.

Next, the concentration of O₃ in O₂ as a reactive gas was adjusted to 200 g/m³ and the reactive gas was introduced into the deposition chamber as shown in Table 1, and the chamber was purged for 10 seconds. At this time, the substrate on which a thin film was to be formed was heated under the temperature conditions shown in Table 1 below.

This process was repeated 100 to 400 times to form a self-limiting atomic layer thin film with a thickness of 10 nm.

For thin films obtained in Example 1 and Comparative Examples 1 to 5, deposition rate reduction rate (D/R reduction rate), SIMS C impurities, and step coverage were measured according to the following methods, and the results are shown in Table 1 and FIG. 2 below.

Deposition rate reduction rate (D/R (dep. rate) reduction rate): The deposition rate reduction rate represents the rate of reduction in the deposition rate after the shielding agent is added compared to the deposition rate before the step coverage improver is added, and was calculated as a percentage using the measured Å/cycle values.

Specifically, using an ellipsometer which is a device capable of measuring optical properties such as thickness and refractive index of the thin film by using the polarization characteristics of light for the manufactured thin film, the thickness of the thin film was measured. Then, the thickness of the thin film deposited per cycle was calculated by dividing the measured thickness by the number of cycles. Based on these results, the thin film growth rate reduction rate was calculated. Specifically, the calculation was performed using Equation 1 below.

$$Deposition rate reduction rate = [ \{ ( D {R}_{i} ) - ( D {R}_{f} ) \} / ( D {R}_{i} ) ] \times 100 \qquad [ Equation 1 ]$$

In Equation 1, deposition rate (DR, Å/cycle) is the speed at which a thin film is deposited. In the deposition of a thin film formed from a precursor and a reactant, DRᵢ (initial deposition rate) is the deposition rate of the thin film formed without adding a step coverage improver. DR_{f} (final deposition rate) is the deposition rate of the thin film formed by adding the step coverage improver during the above process. Here, the deposition rate (DR) is a value measured at room temperature and pressure using an ellipsometer for a thin film with a thickness of 3 to 30 nm, and is expressed in a unit of Å/cycle.
To evaluate the non-uniformity, the maximum and minimum thicknesses were selected from the thicknesses of the thin film measured by the ellipsometer, and the results calculated using Equation 2 below are shown in Table 1 below. Specifically, the thickness of four locations on the east, west, south, and north edges of a 300 mm wafer and the thickness of one location in the center were measured.

$$Non - uniformity ( \% ) = [ \{ ( maximum thickness - minimum thickness ) / 2 \} \times Average thickness ] \times 100 \qquad [ Equation 2 ]$$

SIMS (Secondary-ion mass spectrometry) C impurities: A thin film was axially dug into by an ion sputter, and the C impurity value was confirmed in the SIMS graph by considering the C impurities content (counts) at the moment corresponding to the middle of the deposited thin film by etching to a depth of less contamination in the substrate surface layer, typically 5 nm or more. The results are shown in Table 1 and FIG. 2 below.
Step coverage (%): TEM measurements were taken on specimens cut horizontally at positions 100 nm downward from the upper portion (left drawing) and 100 nm upward from the lower portion (right drawing) of thin films deposited on a substrate of a complex structure with an aspect ratio of 22:1 by Examples 1 and 2 and Comparative Examples 1 to 3, and the step coverage was measured by Equation 3 below.

$$Step coverage \% = ( Thickness deposited on inner wall of lower portion / Thickness deposited on inner wall of upper portion ) \times 100 \qquad [ Equation 3 ]$$

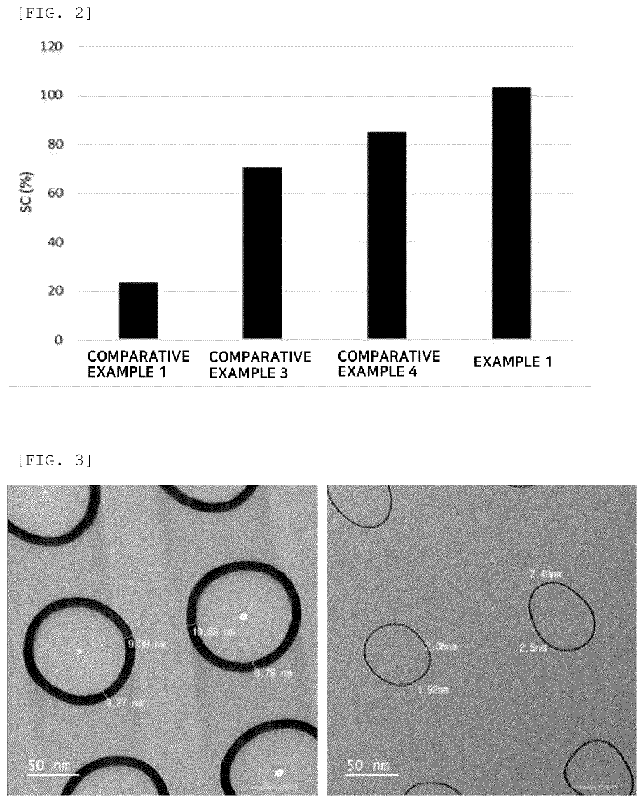

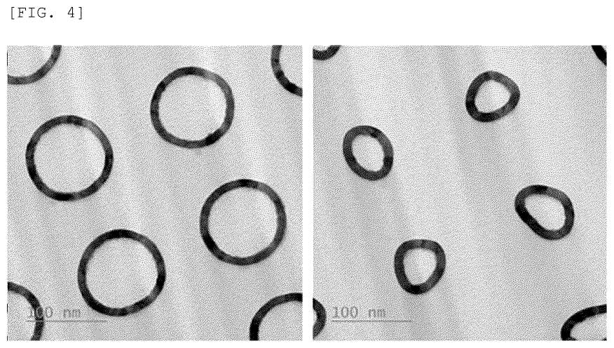

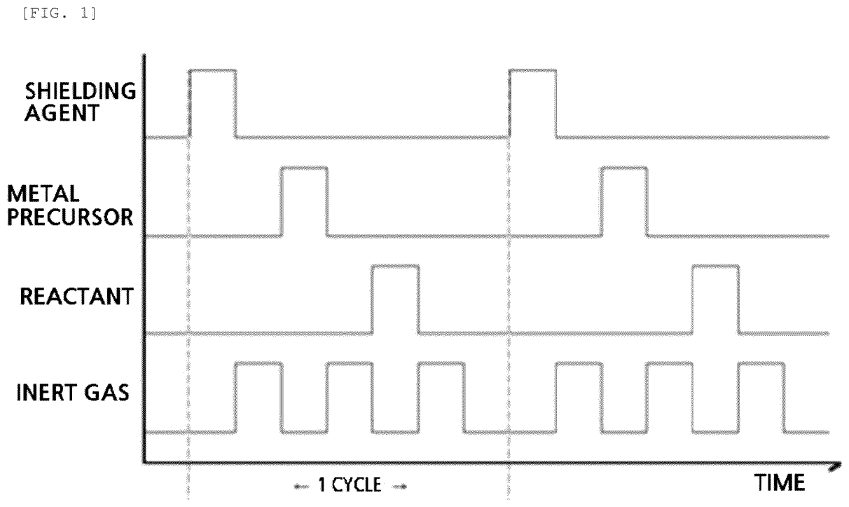

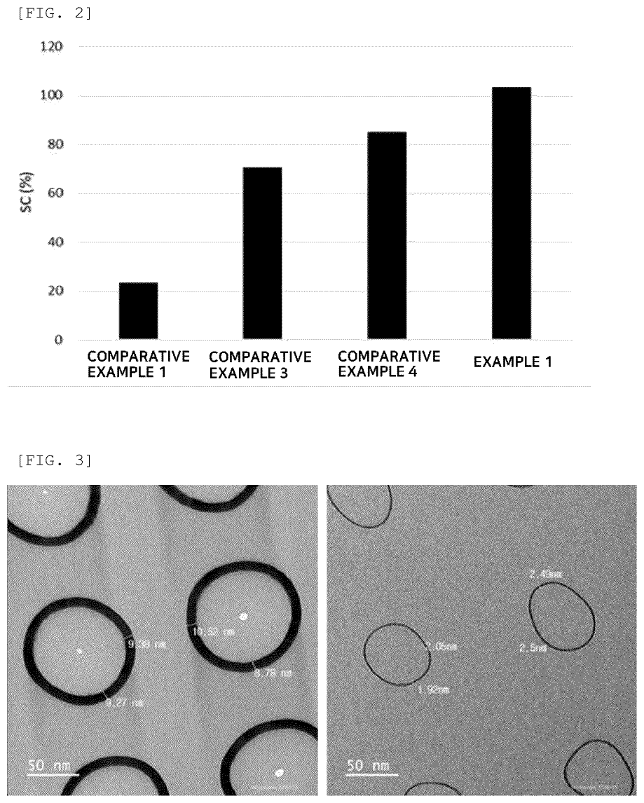

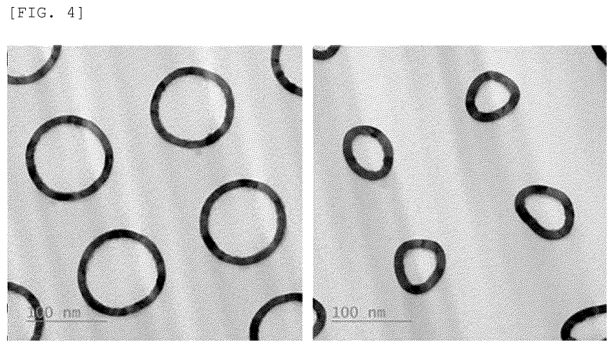

Specifically, on a substrate of a complex structure with an upper portion diameter of 90 nm, a lower portion diameter of 65 nm, a via hole depth of approximately 2000 nm, an aspect ratio of 22:1, a deposition process was performed using diffusion improving agent application conditions. Then, to confirm the thickness uniformity and step coverage deposited inside the vertically formed via hole, a specimen was prepared by cutting horizontally at a position 100 nm downward from the upper portion and at a position 100 nm upward from the lower portion. Then, the specimen was observed using a transmission electron microscope (TEM), and the results are shown in Table 1 and FIGS. 3 to 4 below.

TABLE 1

| | | | Step | | | | Step | | | | | |
|---|---|---|---|---|---|---|---|---|---|---|---|---|
| | | | coverage | Depo- | Pre- | Reac- | coverage | Depo- | Non- | Equa- | | Step |
| | | Reac- | improver | sition | cursor | tion gas | improver | sition | unifor- | tion 1 | SIMSC | coverage |
| | Pre- | tion | (Chemical | temper- | injection | injection | injection | rate | mity | calcu- | analysis | (22: 1 S/C) |
| No. | cursor | gas | Formula No.) | ature | condition | condition | condition | (Å/cycle) | (%) | lation | (counts/s) | (%) |
| Comparative | CpHf | O₃ | — | 420° C. | VFC, | 5 s, | — | 0.93 | 1.22 | — | 428.9 | 23.6 |
| Example1 | | | | | 3 s, | 500 sccm | | | | | | |
| | | | | | 100 sccm | | | | | | | |
| Comparative | CpHf | O₃ | Chemical | 400° C. | VFC, | 5 s, | 30 mg/ | 0.85 | 3.87 | 9% | 524.3 | 75.6 |
| Example2 | | | Formula | | 3 s, | 500 sccm | cycle | | | | | |
| | | | 1-8 | | 100 sccm | | | | | | | |
| Comparative | CpHf | O₃ | Chemical | 400° C. | VFC, | 5 s, | 30 mg/ | 0.79 | 4.14 | 15% | 537.5 | 70.7 |
| Example3 | | | Formula | | 3 s, | 500 sccm | cycle | | | | | |
| | | | 1-9 | | 100 sccm | | | | | | | |
| Comparative | CpHf | O₃ | Chemical | 400° C. | VFC, | 5 s, | 30 mg/ | 0.58 | 23.82 | 37% | 600.9 | 84.9 |
| Example4 | | | Formula | | 3 s, | 500 sccm | cycle | | | | | |
| | | | 1-10 | | 100 sccm | | | | | | | |
| Comparative | CpHf | O₃ | Chemical | 400° C. | VFC, | 5 s, | 30 mg/ | 0.67 | 6.84 | 28% | 583.7 | N/A |
| Example5 | | | Formula | | 3 s, | 500 sccm | cycle | | | | | |
| | | | 1-7 | | 100 sccm | | | | | | | |
| Example1 | CpHf | O₃ | Chemical | 420° C | VFC, | 5 s, | 30 mg/ | 0.59 | 3.08 | 36% | 484.5 | 103.5 |
| | | | Formula | | 3 s, | 500 sccm | cycle | | | | | |
| | | | 1-6 | | 100 sccm | | | | | | | |

In Table 1, CpHf is an abbreviation for tris(dimethylamido)cyclopentadienyl hafnium.

As shown in Table 1 and FIG. 2 below, compared to Comparative Example 1 without using the step coverage improver of the present invention, Example 1 using the step coverage improver of the present invention exhibited excellent step coverage.

In addition, compared to Comparative Examples 2 to 5 using a step coverage improver of a different kind from the step coverage improver of the present invention, in Example 1 using the step coverage improver of the present invention, the deposition rate reduction rate was improved, and impurity reduction characteristics and step coverage were excellent.

Through this, it is expected that effective step coverage will be implemented even on a pattern substrate with a high aspect ratio. In fact, the step coverage measured according to Comparative Examples 1 to 4 was 23.6% or more, up to 84.9%, while the step coverage measured according to Example 1 of the present invention was 103.5%, showing excellent step coverage (see FIGS. 3 and 4 below).

1. A step coverage improver, comprising a compound represented by Chemical Formula 1 below.
[Chemical Formula 1] 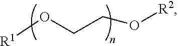
wherein R1 and R2 are independently H or an alkyl group having 1 to 5 carbon atoms, and n is an integer from 2 to 4.

2. The step coverage improver according to claim 1, wherein the step coverage improver comprises one or more selected from compounds represented by Chemical Formulas 1-1 to 1-6 below.
[Chemical Formulas 1-1 to 1-6]

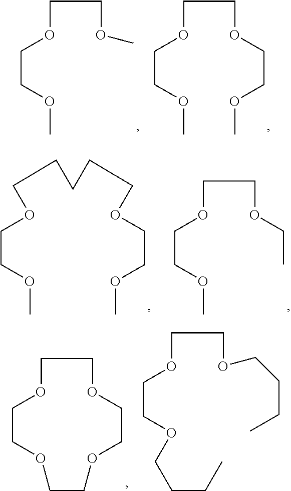

3. The step coverage improver according to claim 1, wherein the step coverage improver provides a shielded area for an oxide film, a nitride film, a metal film, or a selective thin film thereof, and the shielded area is formed on an entire or part of a substrate on which the oxide film, the nitride film, the metal film, or the selective thin film thereof is formed.

4. The step coverage improver according to claim 1, wherein the thin film improves step coverage in a process of forming a laminated film of one or more selected from the group consisting of Al, Si, Ti, V, Co, Ni, Cu, Zn, Ga, Ge, Se, Zr, Nb, Mo, Ru, Rh, In, Sn, Sb, Te, Hf, Ta, W, Re, Os, Ir, La, Ce, and Nd.

5. A method of forming a thin film, comprising injecting a step coverage improver represented by Chemical Formula 1 below into a chamber to shield a surface of a loaded substrate.
[Chemical Formula 1] 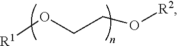
wherein R1 and R2 are independently H or an alkyl group having 1 to 5 carbon atoms, and n is an integer from 2 to 4.

6. The method according to claim 5, wherein the chamber is an ALD chamber, a CVD chamber, a PEALD chamber, or a PECVD chamber.

7. The method according to claim 5, wherein the step coverage improver is transferred to the chamber by a VFC, DLI, or LDS method, and the thin film is a silicon nitride film, a silicon oxide film, a titanium nitride film, a titanium oxide film, a tungsten nitride film, a molybdenum nitride film, a hafnium oxide film, a zirconium oxide film, a tungsten oxide film, or an aluminum oxide film.

8. A semiconductor substrate, comprising the thin film manufactured using the method according to claim 5.

9. The semiconductor substrate according to claim 8, wherein the thin film has a multilayer structure of two or more layers.

10. A semiconductor device, comprising the semiconductor substrate according to claim 8.
